(19) United States
(12) Patent Application Publication
(10) Pub. No.: US 2010/0237481 A1
(43) Pub. Date: Sep. 23, 2010

(54) INTEGRATED CIRCUIT PACKAGING SYSTEM WITH DUAL SIDED CONNECTION AND METHOD OF MANUFACTURE THEREOF

(76) Inventors: HeeJo Chi, Daejeon-si (KR); NamJu Cho, Uiwang-si (KR); Taewoo Lee, Icheon-Si (KR)

Correspondence Address: LAW OFFICES OF MIKIO ISHIMARU, 333 W. EL CAMINO REAL, SUITE 330, SUNNYVALE, CA, 94087, US

(21) Appl. No.: 12/408,641

(22) Filed: Mar. 20, 2009

(51) Int. Cl. H01L 23/28; H01L 21/56; H01L 23/48; H01L 23/52

(52) U.S. Cl. 257/685; 438/124; 257/698; 257/778; 257/E23.116; 257/E23.01; 257/E23.141; 257/E21.502

(57) ABSTRACT

A method of manufacture of an integrated circuit packaging system includes: attaching an integrated circuit having a through via over a substrate with the through via coupled to the substrate; attaching a conductive support over the substrate and adjacent to the integrated circuit; forming an encapsulation over the substrate with the conductive support exposed from the encapsulation; and attaching an external interconnect under the substrate.

### TECHNICAL FIELD

The present invention relates generally to an integrated circuit packaging system, and more particularly to an integrated packaging system with a dual sided connection.

### BACKGROUND ART

Increased miniaturization of components, greater packaging density of integrated circuits (“ICs”), higher performance, and lower cost are ongoing goals of the computer industry. Semiconductor package structures continue to advance toward miniaturization, to increase the density of the components that are packaged therein while decreasing the sizes of the products that are made therefrom. This is a response to continually increasing demands on information and communication products for ever-reduced sizes, thicknesses, and costs along with ever-increasing performance.

These increasing requirements for miniaturization are particularly noteworthy, for example, in portable information and communication devices such as cellular phones, hands-free cellular phone headsets, personal data assistants (“PDA's”), camcorders, notebook computers, and so forth. All of these devices continue to be made smaller and thinner to improve their portability. Accordingly, large-scale IC (“LSI”) packages that are incorporated into these devices are required to be made smaller and thinner. The package configurations that house and protect LSI require them to be made small and thinner as well.

Many conventional semiconductor (or “chip”) packages are of the type where a semiconductor die is molded into a package with a resin, such as an epoxy molding compound. Numerous package approaches stack multiple integrated circuit dice or package in package (PIP) or a combination. Other approaches include package level stacking or package on package (POP).

Thus, a need still remains for an integrated circuit packaging system providing high connectivity, low cost manufacturing, and reduced size. In view of the ever-increasing need to save costs and improve efficiencies, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including attaching an integrated circuit having a through via over a substrate with the through via couple to the substrate; attaching a conductive support overt the substrate and adjacent to the integrated circuit; forming an encapsulation over the substrate with the conductive support exposed from the encapsulation; and attaching an external interconnect under the substrate.

The present invention provides an integrated circuit packaging system, including: a substrate; an integrated circuit having a through via over the substrate with the through via coupled to the substrate; a conductive support over the substrate with the conductive support exposed from the encapsulation; and an external interconnect attached under the substrate.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a top view of an integrated circuit packaging system in a first embodiment of the present invention.

FIG. 2 is a cross-sectional view of the integrated circuit packaging system along line 2-2 of FIG. 1.

FIG. 3 is a top view of an integrated circuit packaging system in a second embodiment of the present invention.

FIG. 4 is a cross-sectional view of the integrated circuit packaging system along line 4-4 of FIG. 3.

FIG. 5 is a top view of an integrated circuit packaging system in a third embodiment of the present invention.

FIG. 6 is a cross-sectional view of the integrated circuit packaging system along line 6-6 of FIG. 5.

FIG. 7 is a cross-sectional view of an integrated circuit packaging system along line 6-6 of FIG. 5 in a fourth embodiment of the present invention.

FIG. 8 is a top view of an integrated circuit package-on-package system with the integrated circuit package system of FIG. 4 in a fifth embodiment of the present invention.

FIG. 9 is a cross-sectional view of the integrated circuit package-on-package system along line 9-9 of FIG. 8.

FIG. 10 is a top view of an integrated circuit package-on-package system with the integrated circuit package system of FIG. 2 in a sixth embodiment of the present invention.

FIG. 11 is a cross-sectional view of the integrated circuit packaging system along line 11-11 of FIG. 10.

FIG. 12 is a flow chart of a method of manufacture of an integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

The same numbers are used in all the drawing FIGs. to relate to the same elements. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact among elements.

The term “processing” as used herein includes deposition of material or photoresist, patterning, exposure, development, etching, cleaning, and/or removal of the material or photoresist as required in forming a described structure.

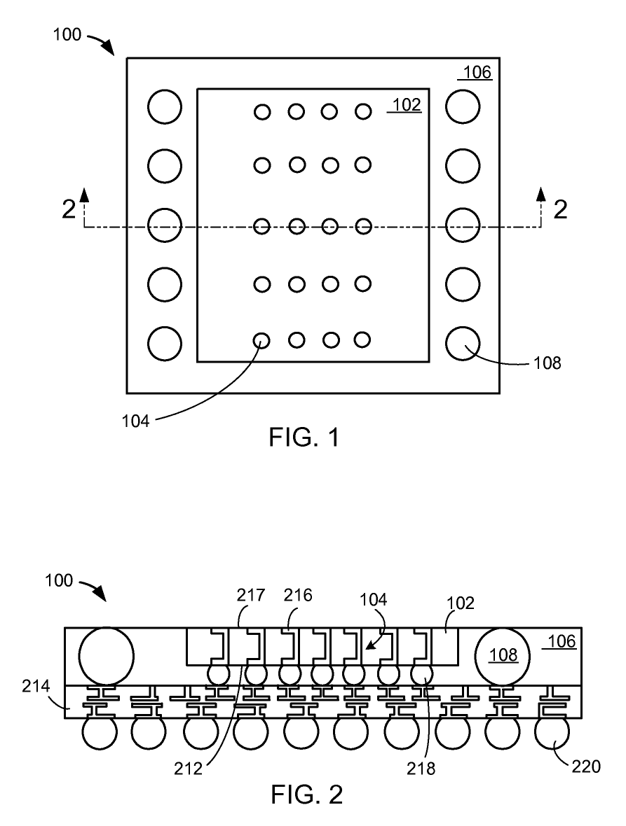

Referring now to FIG. 1, therein is shown a top view of an integrated circuit packaging system 100 in a first embodiment of the present invention. The top view depicts an integrated circuit 102, such as an integrated circuit die or a flip chip, having a through via 104, such as an electrical connection filled with a conductive material, copper, solder, or tungsten.

An encapsulation 106, such as cover including an epoxy molding compound, can expose the integrated circuit 102 and the through via 104. The encapsulation 106 can also expose a conductive support 108, such as a solder ball, a conductive post, or a conductive column, adjacent to the integrated circuit 102.

Referring now to FIG. 2, therein is shown a cross-sectional view of the integrated circuit packaging system 100 along line 2-2 of FIG. 1. The cross-sectional view of the integrated circuit packaging system 100 depicts an active side 212 of the integrated circuit 102 facing a substrate 214, such as a laminated substrate or a printed circuit board. The active side 212 includes active circuitry thereon.

The through via 104 can include a mounting pad 216 at a non-active side 217 of the integrated circuit 102. The non-active side 217 does not include active circuitry thereon. The through via 104 traverses the integrated circuit 102 from the active side 212 to the non-active side 217. The mounting pad 216 can be exposed from the encapsulation 106. The through via 104 can be coupled to the substrate 214. The conductive support 108 can be mounted over the substrate 214 and adjacent to the integrated circuit 102.

The integrated circuit 102 can include a first device interconnect 218, such as a solder ball, conductive bump, or a conductive post, between the through via 104 and the substrate 214. The first device interconnect 218 can also attach between the active side 212 and the substrate 214 without attaching to the through via 104.

The encapsulation 106 can be coplanar with the non-active side 217 providing a planar surface for a mounting surface. An external interconnect 220, such as solder balls or conductive bumps, can attach under the substrate 214.

It has been discovered that the present invention provides the integrated circuit packaging system 100 having a dual connectivity and compact footprint. The conductive support 108 and the through via 104 along with the external interconnect 220 provide dual connectivity from above and below the integrated circuit packaging system 100. The through via 104 and the compact placement of the conductive support 108 adjacent to the integrated circuit 102 eliminates the need for a separate connection structure, such as an interposer, that can require additional footprint space.

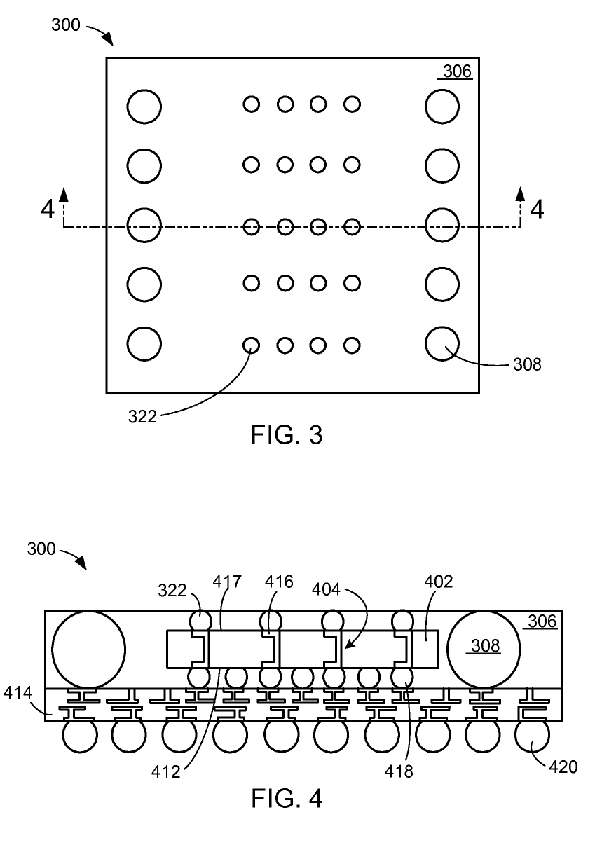

Referring now to FIG. 3, therein is shown a top view of an integrated circuit packaging system 300 in a second embodiment of the present invention. The top view of the integrated circuit packaging system 300 depicts an encapsulation 306, such as cover including an epoxy molding compound.

The encapsulation 306 can expose a second device interconnect 322, such as a solder ball or a conductive post, towards an interior of the encapsulation 306. The encapsulation 306 can also expose a conductive support 308, such as a solder ball, a conductive post, or a conductive column, toward the periphery of the encapsulation 306.

For illustrative purposes, the integrated circuit packaging system 300 is shown with the second device interconnect 322 in an array configuration, although it is understood that the integrated circuit packaging system 300 can have a different configuration with the second device interconnect 322. For example, the second device interconnect 322 can form a peripheral configuration or an array configuration with some of the array location depopulated.

Referring now to FIG. 4, therein is shown a cross-sectional view of the integrated circuit packaging system 300 along line 4-4 of FIG. 3. The cross-sectional view of the integrated circuit packaging system 300 depicts an active side 412 of an integrated circuit 402, such as an integrated circuit die or a flip chip, facing a substrate 414, such as a laminated substrate or a printed circuit board.

A through via 404 can include a mounting pad 416 at a non-active side 417 of the integrated circuit 402. The through via 404 traverses the integrated circuit 402 from the active side 412 to the non-active side 417. The mounting pad 416 can be attached to the second device interconnect 322. The through via 404 can be coupled to the substrate 414. The conductive support 308 can be mounted over the substrate 414 and adjacent to the integrated circuit 402.

The integrated circuit 402 can include a first device interconnect 418, such as a solder ball, conductive bump, or a conductive post, between the through via 404 and the substrate 414. The first device interconnect 418 can also attach between the active side 412 and the substrate 414 without attaching to the through via 404.

The encapsulation 306 can be coplanar with the second device interconnect 322 and the conductive support 308. The encapsulation 306 can provide a planar surface for a mounting surface. An external interconnect 420, such as solder balls or conductive bumps, can attach under the substrate 414.

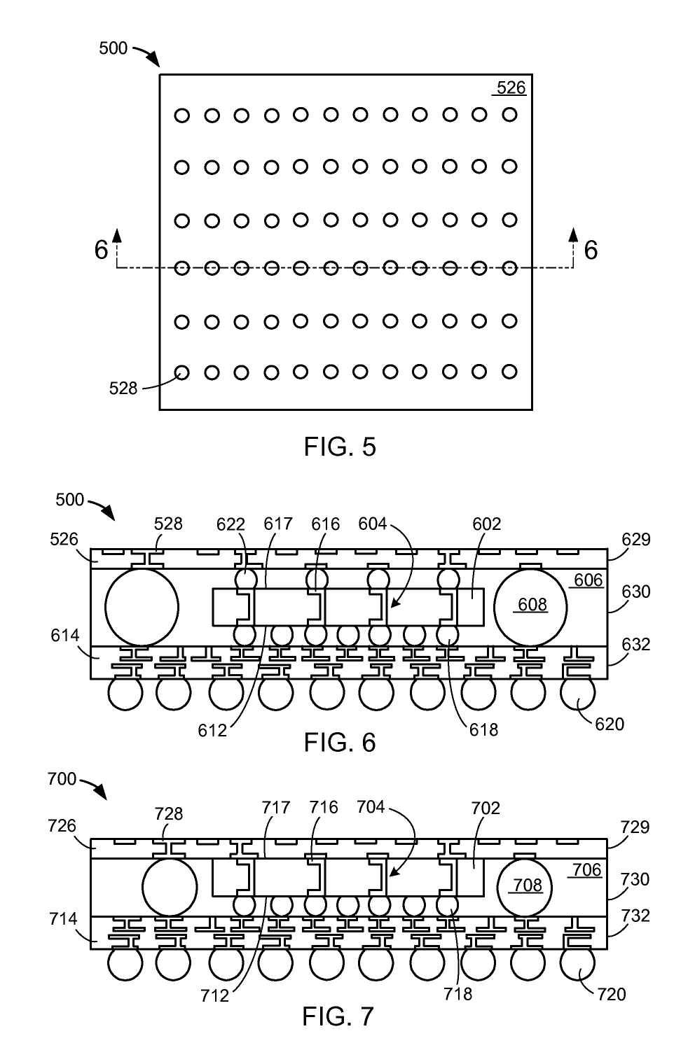

Referring now to FIG. 5, therein is shown a top view of an integrated circuit packaging system 500 in a third embodiment of the present invention. The top view of the integrated circuit packaging system 500 depicts a non-laminated redistribution structure 526. An example of the non-laminated redistribution structure 526 includes a dielectric layer that is metalized by plating with a plurality of conductive metals, such as copper, aluminum, or nickel, and etched by a method such as photolithography. The non-laminated redistribution structure 526 can adhere to the top of the integrated circuit die or the encapsulation. The non-laminated redistribution structure 526 can include a mounting contact 528.

For illustrative purposes, the integrated circuit packaging system 500 is shown with the mounting contact 528 in an array configuration, although it is understood that the integrated circuit packaging system 500 can have a different configuration with the mounting contact 528. For example, the mounting contact 528 can form a peripheral configuration or an array configuration with some of the array location depopulated.

Referring now to FIG. 6, therein is shown a cross-sectional view of the integrated circuit packaging system 500 along line 6-6 of FIG. 5. The cross-sectional view of the integrated circuit packaging system 500 depicts the non-laminated redistribution structure 526 attached over an encapsulation 606, such as cover including an epoxy molding compound.

The cross-sectional view also depicts an active side 612 of an integrated circuit 602, such as an integrated circuit die or a flip chip, facing a substrate 614, such as a laminated substrate or a printed circuit board.

A through via 604 can include a mounting pad 616 at a non-active side 617 of the integrated circuit 602. The through via 604 traverses the integrated circuit 602 from the active side 612 to the non-active side 617. The mounting pad 616 can be attached to a second device interconnect 622. The through via 604 can be coupled to the substrate 614. A conductive support 608, such as a solder ball, a conductive post, or a conductive column, can be mounted over the substrate 614 and adjacent to the integrated circuit 602.

The integrated circuit 602 can include a first device interconnect 618, such as a solder ball, conductive bump, or a conductive post, between the through via 604 and the substrate 614. The first device interconnect 618 can also attach between the active side 612 and the substrate 614 without attaching to the through via 604.

The encapsulation 606 can be coplanar with the second device interconnect 622 and the conductive support 608. The encapsulation 606 can provide a planar surface for a mounting surface. An external interconnect 620, such as solder balls or conductive bumps, can attach under the substrate 614.

A redistribution edge 629 of the non-laminated redistribution structure 526 can be coplanar with a vertical side 630 of the encapsulation 606 and a substrate edge 632 of the substrate 614. The conductive support 608 can be attached to the non-laminated redistribution structure 526. The conductive support 608 can be coupled to the mounting contact 528. The second device interconnect 622 can be attached to the mounting pad 616 coupled to the through via 604 at the non-active side 617. The second device interconnect 622 can be coupled to the mounting contact 528.

Referring now to FIG. 7, therein is shown a cross-sectional view of an integrated circuit packaging system 700 along line 6-6 of FIG. 5 in a fourth embodiment of the present invention. The cross-sectional view of the integrated circuit packaging system 700 depicts a non-laminated redistribution structure 726, such as a non-laminated structure including an insulator, copper, aluminum, or other conductive lines, attached over an encapsulation 706, such as cover including an epoxy molding compound.

The cross-sectional view also depicts an active side 712 of an integrated circuit 702, such as an integrated circuit die or a flip chip, facing a substrate 714, such as a laminated substrate or a printed circuit board.

A through via 704 can include a mounting pad 716 at a non-active side 717 of the integrated circuit 702. The through via 704 traverses the integrated circuit 702 from the active side 712 to the non-active side 717. The mounting pad 716 can be attached to the non-laminated redistribution structure 726 and can be coupled to a mounting contact 728. The through via 704 can be coupled to the substrate 714. A conductive support 708, such as a solder ball, a conductive post, or a conductive column, can be mounted over the substrate 714 and adjacent to the integrated circuit 702.

The integrated circuit 702 can include a first device interconnect 718, such as a solder ball, conductive bump, or a conductive post, between the through via 704 and the substrate 714. The first device interconnect 718 can also attach between the active side 712 and the substrate 714 without attaching to the through via 704.

The encapsulation 706 can be coplanar with the conductive support 708 and the non-active side 717. The non-laminated redistribution structure 726 can be attached to the non-active side 717. An external interconnect 720, such as solder balls or conductive bumps, can attach under the substrate 714.

A redistribution edge 729 of the non-laminated redistribution structure 726 can be coplanar with a vertical side 730 of the encapsulation 706 and a substrate edge 732 of the substrate 714. The conductive support 708 can be attached to the non-laminated redistribution structure 726.

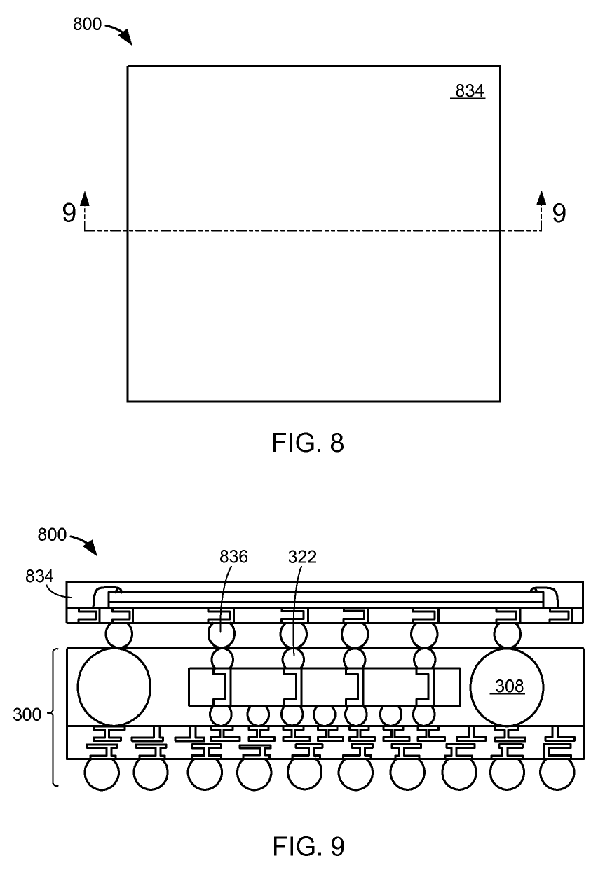

Referring now to FIG. 8, therein is shown a top view an integrated circuit package-on-package system 800 with the integrated circuit packaging system 300 of FIG. 4 in a fifth embodiment of the present invention. The top view depicts a mounting device 834, such as an integrated circuit die or a packaged integrated circuit.

Referring now to FIG. 9, therein is shown a cross-sectional view of the integrated circuit package-on-package system 800 along line 9-9 of FIG. 8. The cross-sectional view depicts the mounting device 834 mounted over the integrated circuit packaging system 300. A mounting interconnect 836 of the mounting device 834 can attach to the second device interconnect 322 and the conductive support 308.

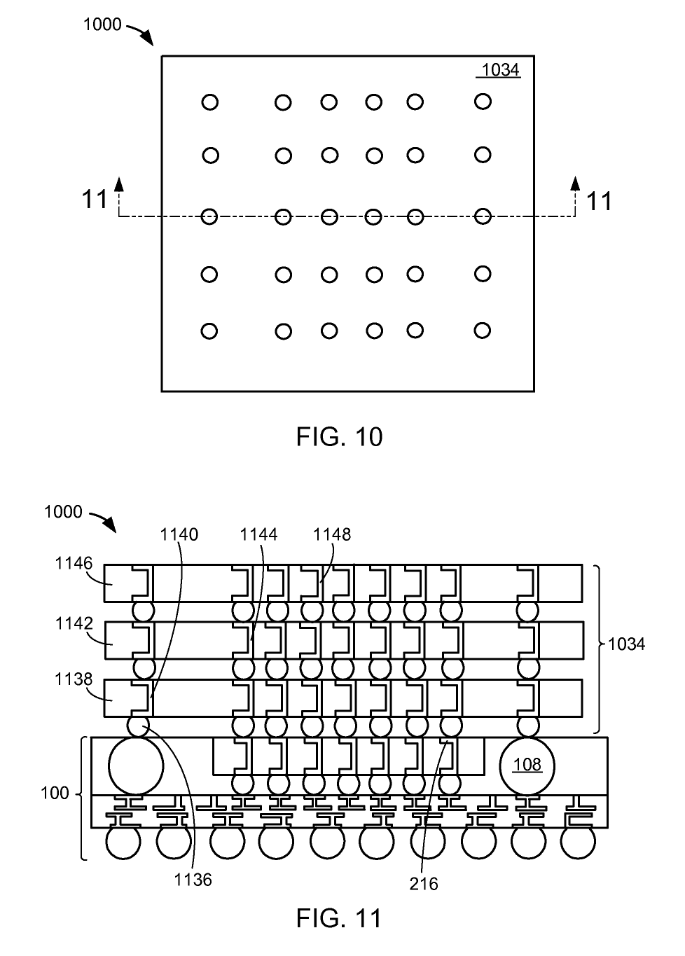

Referring now to FIG. 10, therein is shown a top view of an integrated circuit package-on-package system 1000 with the integrated circuit packaging system 100 of FIG. 2 in a sixth embodiment of the present invention. The top view depicts a device stack 1034.

Referring now to FIG. 11, therein is shown a cross-sectional view of the integrated circuit package-on-package system 1000 along line 10-10 of FIG. 10. The cross-sectional view depicts the device stack 1034 mounted over the integrated circuit packaging system 100.

The device stack 1034 can include a first device 1138, such as an integrated circuit die or a flip chip, having a first through channel 1140. The device stack 1034 can also include a second device 1142, such as an integrated circuit die or a flip chip, having a second through channel 1144. The device stack 1034 can further include a third device 1146, such as an integrated circuit die or a flip chip, having a third through channel 1148.

The second device 1142 can be over the first device 1138. The third device 1146 can be over the second device 1142. The first device 1138 can be over the integrated circuit packaging system 100.

For illustrative purposes, the integrated circuit package-on-package system 1000 is shown with the first device 1138, the second device 1142, and the third device 1146 as substantially the same, although it is understood that the integrated circuit package-on-package system 1000 can have a different configuration for the device stack 1034. For example, the first device 1138, the second device 1142, and the third device 1146 can be different sizes, have different numbers inputs/output, made from different technologies, and perform different functions.

A mounting interconnect 1136 of the device stack 1034 can attach to the mounting pad 216 and the conductive support 108. The mounting interconnect 1136 can also connect the first through channel 1140 and the second through channel 1144. The mounting interconnect 1136 can further connect the second through channel 1144 and the third through channel 1148.

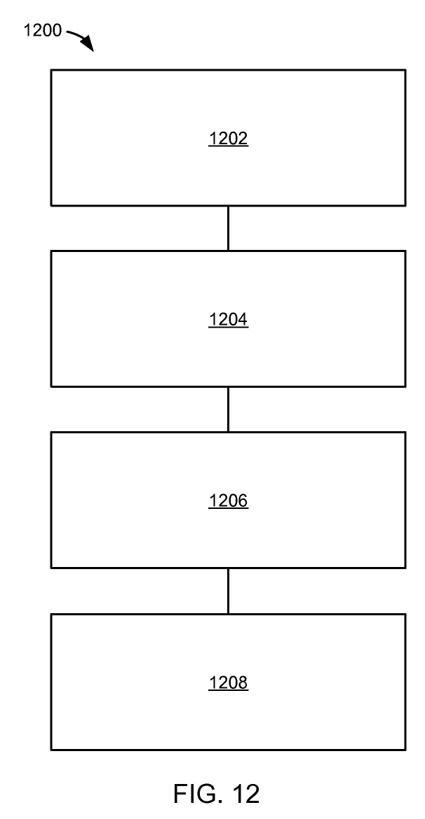

Referring now to FIG. 12, therein is shown a flow chart of a method 1200 of manufacture of the integrated circuit packaging system 100 in an embodiment of the present invention. The method 1200 includes: attaching an integrated circuit having a through via over a substrate with the through via coupled to the substrate in a block 1202; attaching a conductive support over the substrate with the conductive support exposed from the encapsulation in a block 1204; forming an encapsulation over the substrate with the conductive support exposed from the encapsulation in a block 1206; and attaching an external interconnect under the substrate in a block 1208.

The resulting method, device, or system is straightforward, cost-effective, uncomplicated, highly versatile and effective, can be surprisingly and unobviously implemented by adapting known technologies, and is thus readily suited for efficiently and economically manufacturing integrated circuit packaging systems.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
attaching an integrated circuit having a through via over a substrate with the through via coupled to the substrate;
attaching a conductive support over the substrate and adjacent to the integrated circuit;
forming an encapsulation over the substrate with the conductive support exposed from the encapsulation; and
attaching an external interconnect under the substrate.

2. The method as claimed in claim 1 wherein:
attaching the integrated circuit includes facing an active side of the integrated circuit to the substrate; and
forming the encapsulation includes exposing a mounting pad coupled to the through via at a non-active side of the integrated circuit.

3. The method as claimed in claim 1 further comprising:
attaching a second device interconnect to a mounting pad coupled to the through via at a non-active side of the integrated circuit; and
wherein:
forming the encapsulation includes exposing the second device interconnect from the encapsulation.

4. The method as claimed in claim 1 further comprising attaching a non-laminated redistribution structure over the encapsulation includes electrically coupling the conductive support and the through via, at a non-active side of the integrated circuit, to the non-laminated redistribution structure.

5. The method as claimed in claim 1 further comprising:
attaching a second device interconnect to a mounting pad coupled to the through via at a non-active side of the integrated circuit; and
attaching a non-laminated redistribution structure over the encapsulation includes electrically coupling the conductive support and the second device interconnect.

6. A method of manufacture of an integrated circuit packaging system comprising:
attaching an integrated circuit, having a through via and a first device interconnect, over a substrate with the first device interconnect between the through via and the substrate;
attaching a conductive support over the substrate and adjacent to the integrated circuit;
forming an encapsulation over the substrate covering the first device interconnect with the conductive support exposed from encapsulation; and
attaching an external interconnect under the substrate.

7. The method as claimed in claim 6 further comprising attaching a non-laminated redistribution structure over the encapsulation includes:
electrically coupling the conductive support and the through via, at a non-active side of the integrated circuit, to the non-laminated redistribution structure; and
forming a redistribution edge of the non-laminated redistribution structure coplanar with a vertical side of the encapsulation and a substrate edge of the substrate.

8. The method as claimed in claim 6 wherein:
forming the encapsulation includes exposing a second device interconnect coupled to the through via at a non-active side of the integrated circuit; and further comprising:
mounting a first device over the second device interconnect and the conductive support.

9. The method as claimed in claim 6 wherein:
forming the encapsulation includes exposing a mounting pad coupled to the through via at a non-active side of the integrated circuit; and
further comprising:
mounting a first device having a first through channel over the mounting pad and the conductive support; and
mounting a second device having a second through channel over the first through channel.

10. The method as claimed in claim 6 wherein attaching the integrated circuit, having the through via and the first device interconnect, over the substrate includes attaching a flip chip over the substrate.

11. An integrated circuit packaging system comprising:
a substrate;
an integrated circuit having a through via over the substrate with the through via coupled to the substrate;
a conductive support over the substrate and adjacent to the integrated circuit;
an encapsulation over the substrate with the conductive support exposed from the encapsulation; and
an external interconnect attached under the substrate.

12. The system as claimed in claim 11 wherein:
the integrated circuit includes an active side facing the substrate; and
the encapsulation exposes a mounting pad coupled to the through via at a non-active side of the integrated circuit.

13. The system as claimed in claim 11 further comprising:
a second device interconnect attached to a mounting pad coupled to the through via at a non-active side of the integrated circuit; and
wherein:
the encapsulation exposes the second device interconnect.

14. The system as claimed in claim 11 further comprising a non-laminated redistribution structure attached over the encapsulation includes the conductive support and the through via, at a non-active side of the integrated circuit, attached to the non-laminated redistribution structure.

15. The system as claimed in claim 11 further comprising:
a second device interconnect attached to a mounting pad coupled to the through via at a non-active side of the integrated circuit; and
a non-laminated redistribution structure attached to the encapsulation includes the conductive support electrically coupled to the second device interconnect.

16. The system as claimed in claim 11 wherein:
the integrated circuit includes a first device interconnect between the through via and the substrate; and
the encapsulation covers the first device interconnect.

17. The system as claimed in claim 16 further comprising a non-laminated redistribution structure attached to the encapsulation includes:
the conductive support and the through via, at a non-active side of the integrated circuit, electrically coupled to the non-laminated redistribution structure; and
a redistribution edge of the non-laminated redistribution structure coplanar with a vertical side of the encapsulation and a substrate edge of the substrate.

18. The system as claimed in claim 16 wherein:
the encapsulation exposes a second device interconnect coupled to the through via at a non-active side of the integrated circuit; and
further comprising:
a first device over the second device interconnect and the conductive support.

19. The system as claimed in claim 16 wherein:
the encapsulation exposes a mounting pad coupled to the through via at a non-active side of the integrated circuit; and
further comprising:
a first device having a first through channel over the mounting pad and the conductive support; and
a second device having a second through channel over the first through channel.

20. The system as claimed in claim 16 wherein the integrated circuit, having the through via and the first device interconnect, over the substrate includes a flip chip over the substrate.
